(19) United States
(12) Patent Application Publication
(10) Pub. No.: US 2021/0378090 A1
(43) Pub. Date: Dec. 2, 2021

(54) ELECTROMAGNETIC WAVE REDUCING STRUCTURE

(71) Applicant: NEC Corporation, Minato-ku, Tokyo (JP)

(72) Inventor: Kazuhiro KASHIWAKURA, Tokyo (JP)

(73) Assignee: NEC Corporation, Minato-ku, Tokyo (JP)

(21) Appl. No.: 16/322,521

(22) PCT Filed: Aug. 7, 2017
(86) PCT No.: PCT/JP2017/028649

§ 371 Date: Feb. 1, 2019

(30) Foreign Application Priority Data
Aug. 19, 2016 (JP) 2016-161324

(51) Int. Cl. H05K 1/02

(52) U.S. Cl. CPC H05K 1/0231; H05K 1/0298; H05K 1/0215

(57) ABSTRACT

The present invention addresses providing an electromagnetic wave reducing structure that can reduce leakage to outside of noise that is emitted by a circuit, from low frequency to high frequency, without using a special, difficult to obtain item. To address this problem, the electromagnetic wave reducing structure is provided with: a first conductor layer and a second conductor layer facing opposite each other; and a capacitor group comprising a plurality of capacitors connected to the first conductor layer and the second conductor layer. All the gaps are approximately equal between the capacitors in any pair of adjacent capacitors in a first direction within the plane and any pair of adjacent capacitors in a second direction which is the direction within the plane that is approximately perpendicular to the first direction, in a surface parallel to the surface of the first conductor layer that faces opposite the second conductor layer.

### TECHNICAL FIELD

The present invention relates to an electromagnetic wave reducing structure for reducing an electromagnetic wave.

### BACKGROUND ART

It is known that reducing impedance between a power supply and a ground is effective in order to reduce an electromagnetic wave noise generated by a predetermined circuit (refer to PTL 1). Then, in order to reduce this impedance, providing a bypass capacitor (decoupling capacitor) or the like is effective (refer to PTL 2).

However, in recent years, an operating frequency of a large-scale integration (LSI) exceeds GHz, whereby a frequency of a noise electromagnetic wave generated by the LSI has been shifted to a high frequency region. For this reason, a bypass capacitor becomes unable to sufficiently prevent an electromagnetic wave noise generated by the LSI.

PTLs 3 to 6 disclose, as a technique for solving the above-described problem, application techniques of a metamaterial and an electromagnetic band gap (EBG).

PTL 3 discloses a technique of preventing a noise by incorporating, in a printed circuit board, a sheet called “noise prevention layer”.

Further, PTLs 4 to 6 disclose techniques of preventing an electromagnetic wave noise by wiring design of a printed circuit board.

Furthermore, PTL 7 discloses a multilayer wiring board in which an integrated circuit and a plurality of decoupling capacitors connected in parallel with each other between a power supply of the integrated circuit and a ground are mounted.

In addition, PTL 8 discloses a multilayer printed circuit board regarding which a distance between a bypass capacitor and another bypass capacitor arranged on the multilayer printed circuit board is calculated based on information of circuit elements, and bypass capacitors are arranged at equal intervals in a power supply layer, based on the distance.

Further, PTL 9 discloses a voltage fluctuation absorption structure for a circuit board in which capacitors for absorbing voltage fluctuation are arranged along respective sides at an outer periphery of the circuit board, and each of the capacitors is connected to the power-supply-terminal layer and an earth terminal layer.

### CITATION LIST

### Patent Literature

[PTL 1] Japanese Unexamined Patent Application Publication No. 2006-266863

[PTL 2] International Publication No. WO2012/133496

[PTL 3] Japanese Unexamined Patent Application Publication No. 2008-204086

[PTL 4] International Publication No. WO2012/029213

[PTL 5] International Publication No. WO2013/018257

[PTL 6] Japanese Unexamined Patent Application Publication No. 2013-232613

[PTL 7] Japanese Unexamined Patent Application Publication No. 2012-164817

[PTL 8] Japanese Unexamined Patent Application Publication No. 2006-261470

[PTL 9] Japanese Unexamined Patent Application Publication No. H09-266361

### SUMMARY OF INVENTION

### Technical Problem

However, since a sheet material of the “noise prevention layer” disclosed in PTL 3 is a special material, and thus, there is a problem that the sheet material is difficult to acquire and is expensive. Further, the techniques disclosed in PTLs 4 to 6 are impractical since a structure becomes too large in size for being applicable also to a low frequency range (30 MHz to 1 GHz).

An object of the present invention is to provide an electromagnetic wave reducing structure that can reduce leakage, to an outside, of a noise generated by a circuit, in a range from a low-frequency region to a high-frequency region, without using a special material difficult to acquire.

### Solution to Problem

An electromagnetic wave reducing structure according to the present invention includes a first conductor layer and a second conductor layer facing to each other; and a capacitor group constituted of a plurality of capacitors connected to the first conductor layer and the second conductor layer, wherein every inter-capacitor interval between any one pair of the capacitors adjacent to each other in an in-plane first direction in a plane parallel to a surface that belongs to the first conductor layer and that faces the second conductor layer, and between any one pair of the capacitors adjacent to each other in a second direction that is a direction in the plane being substantially perpendicular to the first direction is substantially identical, and the capacitor group includes a plurality of rectangular arrays of the capacitors in the plane, the arrays surrounding an arrangement position of a circuit and not overlapping each other.

### Advantageous Effects of Invention

An electromagnetic wave reducing structure according to the present invention can reduce outward leakage of a noise generated by a circuit, in a range from a low-frequency region to a high-frequency region, without using a special material difficult to acquire.

### BRIEF DESCRIPTION OF DRAWINGS

FIG. 1 is a concept diagram illustrating a configuration example of an electromagnetic wave reducing structure according to the present example embodiment.

FIG. 2 is a concept diagram illustrating an example of manufacturing steps for the electromagnetic wave reducing structure according to the present example embodiment.

FIG. 3 is a concept diagram illustrating a cross section of an electromagnetic wave reducing structure in which an array of capacitors is provided on a substrate.

FIG. 4 is a concept diagram illustrating a detailed structure example of a portion 291a illustrated in FIG. 3.

FIG. 5 is a concept diagram illustrating an example of an installation of a circuit in the electromagnetic wave reducing structure according to the present example embodiment.

FIG. 6 is a diagram (part 1) illustrating a model of an electromagnetic wave reducing structure used in a first simulation.

FIG. 7 is a diagram (part 2) illustrating a model of an electromagnetic wave reducing structure used in the first simulation.

FIG. 8 is a diagram illustrating a result of the first simulation of a frequency characteristic of an impedance between conductor layers.

FIG. 9 is a diagram illustrating a result of the first simulation of a noise propagation characteristic in a substrate.

FIG. 10 is a diagram illustrating a result of the first simulation of a characteristic of electric field radiation to an outside of the substrate.

FIG. 11 is a diagram (part 2) illustrating a model of an electromagnetic wave reducing structure used in a second simulation.

FIG. 12 is a diagram illustrating a result of the second simulation of a frequency characteristic of an impedance between conductor layers.

FIG. 13 is a diagram illustrating a result of the second simulation of a noise propagation characteristic in a substrate.

FIG. 14 is a diagram illustrating a result of the second simulation of a characteristic of electric field radiation to an outside of the substrate.

FIG. 15 is a concept diagram (part 1) illustrating an example of installation of capacitors to three circuits installed on a substrate.

FIG. 16 is a concept diagram (part 2) illustrating an example of installation of capacitors to three circuits installed on the substrate.

FIG. 17 is a concept diagram (part 3) illustrating an example of installation of capacitors to three circuits installed on the substrate.

FIG. 18 is a concept diagram (part 4) illustrating an example of installation of capacitors to three circuits installed on the substrate.

FIG. 19 is a concept diagram illustrating the minimum configuration of an electromagnetic wave reducing structure according to the present invention.

### EXAMPLE EMBODIMENT

### [Configuration]

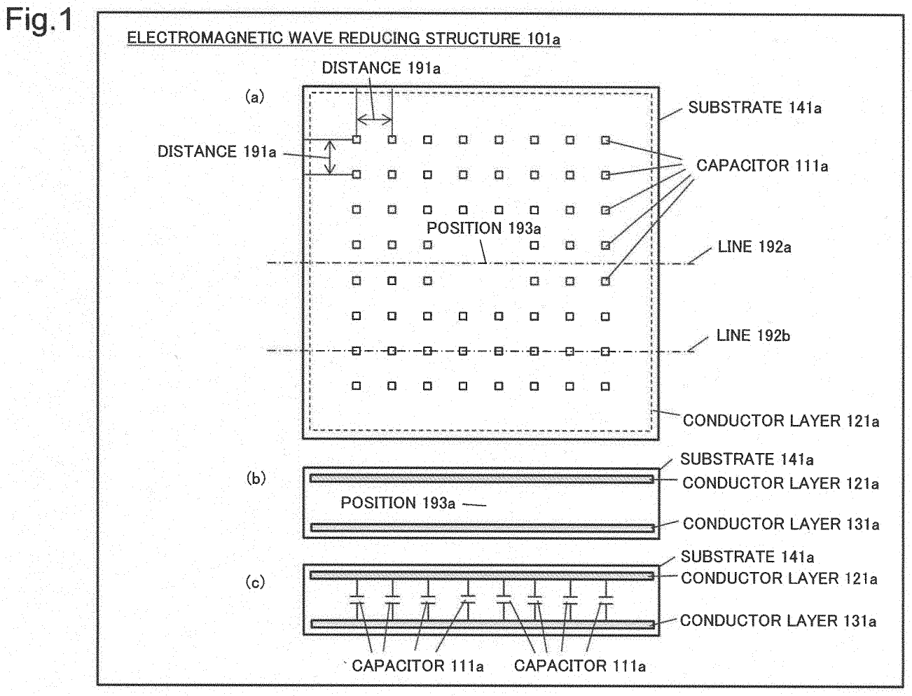

FIG. 1 is a concept diagram illustrating a configuration of an electromagnetic wave reducing structure 101a that is an example of an electromagnetic wave reducing structure according to the present example embodiment. FIG. 1(a) is a top view of the electromagnetic wave reducing structure 101a. FIG. 1(b) is a cross-sectional view in the assumed case where the electromagnetic wave reducing structure 101a is cut along a line 192a illustrated in FIG. 1(a). Further, FIG. 1(c) is a cross-sectional view in the assumed case where the electromagnetic wave reducing structure 101a is cut along a line 192b illustrated in FIG. 1(a).

Hereinafter, “upper”, “lower”, “right”, and “left” are assumed to be “upper”, “lower”, “right”, and “left” in front of each of the drawings.

A position 193a is a position where a predetermined circuit as a generation source of an electromagnetic wave noise is assumed to be installed.

The electromagnetic wave reducing structure 101a is a structure for reducing leakage, to an outside of the electromagnetic wave reducing structure 101a, of an electromagnetic wave generated by the circuit.

The electromagnetic wave reducing structure 101a includes a substrate 141a, 60 capacitors 111a, and conductor layers 121a and 131a. All the smallest squares illustrated in FIG. 1(a) each represent the capacitor 111a.

The conductor layer 121a is formed at a position, in the substrate 141a, illustrated in FIG. 1(a) and illustrated on upper sides in FIG. 1(b) and FIG. 1(c). The conductor layer 121a is a power supply layer for supplying voltage to the circuit, for example.

The conductor layer 131a is formed at a position, in the substrate 141a, illustrated at the same position as the conductor layer 121a in FIG. 1(a) and illustrated on lower sides in FIG. 1(b) and FIG. 1(c). The conductor layer 131a is a ground layer for grounding the circuit, for example.

Each of the capacitors 111a is formed between the conductor layer 121a and the conductor layer 131a in such a way as to be connected to the conductor layer 121a and the conductor layer 131a. Every distance 191a between the two capacitors 111a adjacent to each other is the same to each other, except near the position 193a.

As the capacitor 111a, for example, a commercially available chip capacitor can be used. In this case, the capacitor 111a is embedded in a hole formed in the substrate 141a, for example. Then, a structure is made in such a way that both terminals of the capacitor 111a are electrically connected to the conductor layer 121a and the conductor layer 131a, respectively.

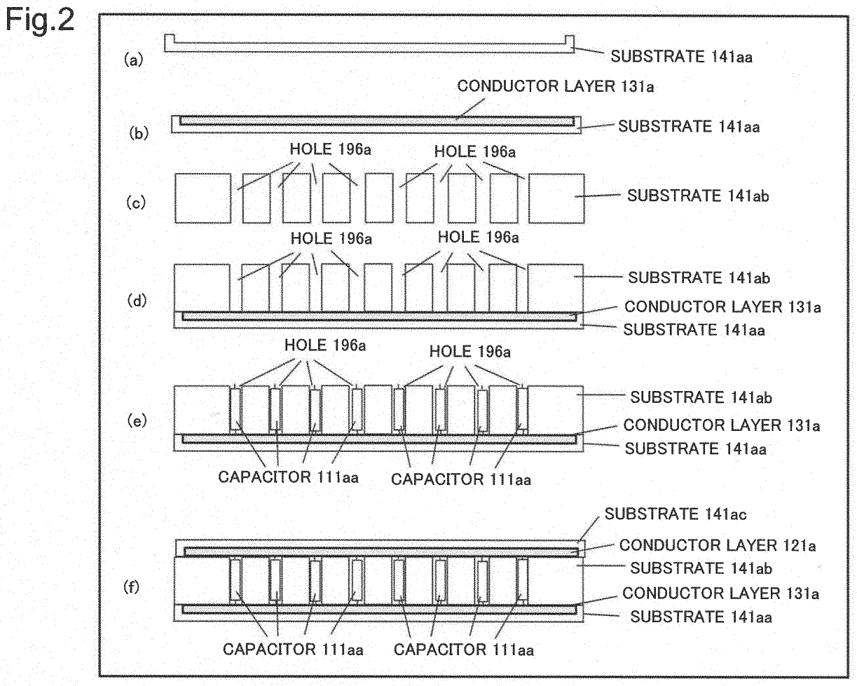

This structure can be manufactured by steps illustrated in FIG. 2(a) to FIG. 2(f), for example.

First, a substrate 141aa as illustrated in FIG. 2 (a) is prepared. The substrate 141aa is a dielectric substrate.

Then, as illustrated in FIG. 2(b), the conductor layer 131a is formed on the substrate 141aa. For example, the conductor layer 131a is formed by vapor deposition of a metal.

Then, as illustrated in FIG. 2(c), a substrate 141ab as a dielectric substrate in which holes 196a are formed is produced.

Then, as illustrated in FIG. 2(d), the substrate 141ab is adhered on the structure illustrated in FIG. 2(b).

Next, as illustrated in FIG. 2(e), capacitors 111aa as chip capacitors are inserted into the respective holes 196a illustrated in FIG. 2(d). The lower terminals of the capacitors 111a are electrically connected to the conductor layer 131a by solder or the like.

Then, as illustrated in FIG. 2(f), a substrate 141ac on which the conductor layer 121a is formed on the lower surface side is adhered on the structure illustrated in FIG. 2(e). At this time, the upper terminals of the respective capacitors 111aa are electrically connected to the conductor layer 121a by solder or the like.

The capacitors to be arranged do not necessarily need to be provided between the two conductor layers.

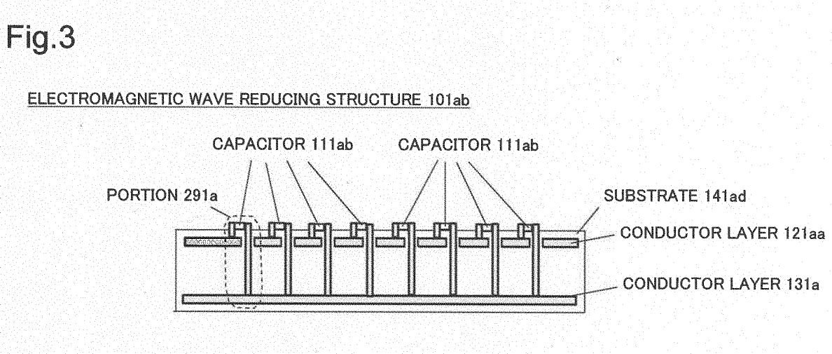

FIG. 3 is a concept diagram illustrating a cross section of an electromagnetic wave reducing structure 101ab in which an array of capacitors 111ab is provided on a substrate 141ad.

The electromagnetic wave reducing structure 101ab includes the substrate 141ad, conductor layers 121aa and 131a, and the capacitors 111ab.

Each of the capacitors 111ab is installed on the substrate 141ad. One terminal of each of the capacitors 111ab is electrically connected to the conductor layer 121aa. Further, the other terminals of the capacitors 111ab are electrically connected to the conductor layer 131a, and are not electrically connected to the conductor layer 121aa.

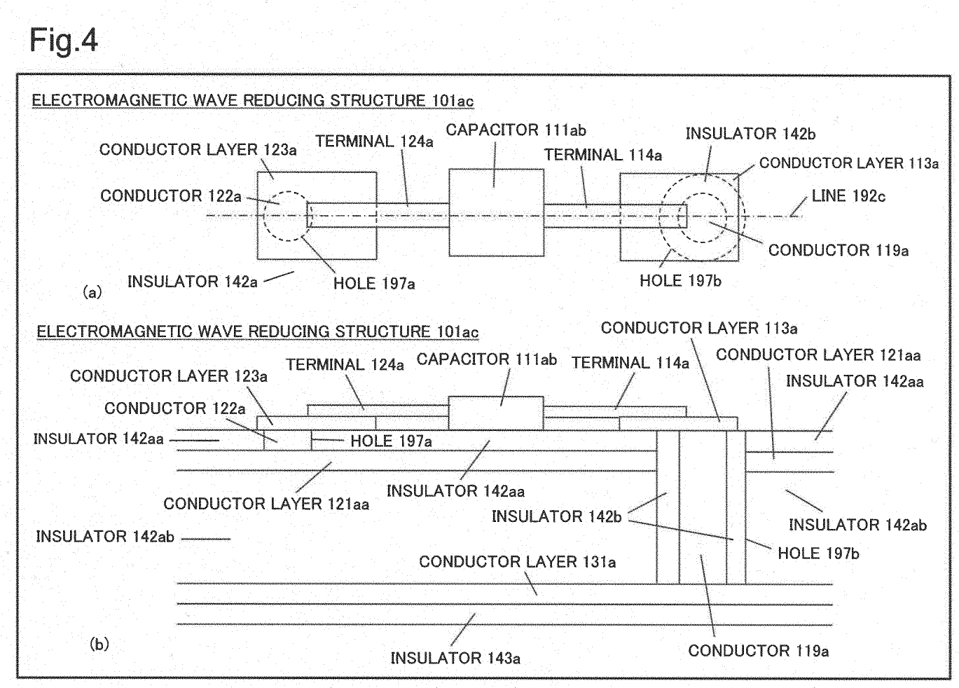

FIG. 4 is a concept diagram illustrating an electromagnetic wave reducing structure 101ac that is a detailed structure example of a portion 291a illustrated in FIG. 3. FIG. 4(a) is a top view in the assumed case where the electromagnetic wave reducing structure 101ac is viewed from the upper side of the capacitor 111ab. Further, FIG. 4(b) is a cross-sectional view in the assumed case where the electromagnetic wave reducing structure 101ac is cut along a line 192c illustrated in FIG. 4(a).

The electromagnetic wave reducing structure 101ac includes insulators 142aa, 142ab, 142b, and 143a, conductor layers 121aa, 131a, 113a, and 123a, conductors 119a and 122a, terminals 114a and 124a, and the capacitor 111ab.

In the electromagnetic wave reducing structure 101ac, the insulator 143a, the conductor layer 131a, the insulator 142ab, the conductor layer 121aa, and the insulator 142aa are formed in this order from the lower side.

In a layered body including the insulator 142aa, the conductor layer 121aa, and the insulator 142ab, a hole 197b is formed. Along a side wall of the hole 197b, the insulator 142b is formed. In an area in the hole 197b where the insulator 142b is not formed, the conductor 119a is formed. A lower surface of the conductor 119a is in contact with the conductor layer 131a. Meanwhile, the conductor 119a is not in contact with the conductor layer 121aa.

In the insulator 142aa, a hole 197a is formed. In the hole 197a, the conductor 122a is formed. A lower surface of the conductor 122a is in contact with the conductor layer 121aa.

The conductor layers 113a and 123a are formed on a structure including the insulator 142aa, the conductor 122a, the insulator 142b, and the conductor 119a. The conductor layer 113a is in contact with an upper surface of the conductor 119a. The conductor layer 123a is in contact with an upper surface of the conductor 122a.

The capacitor 111ab is installed on a structure including the insulator 142aa, the conductor 122a, the insulator 142b, the conductor 119a, and the conductor layers 113a and 123a. The terminal 114a is in contact with the conductor layer 113a, and the terminal 124a is in contact with the conductor layer 123a. Here, the terminals 114a and 124a are terminals of the capacitor 111ab.

With the above-described configuration, the terminal 114a that is one terminal of the capacitor 111ab is electrically connected to the conductor layer 131a, and the terminal 124a that is the other terminal of the capacitor 111ab is electrically connected to the conductor layer 121aa.

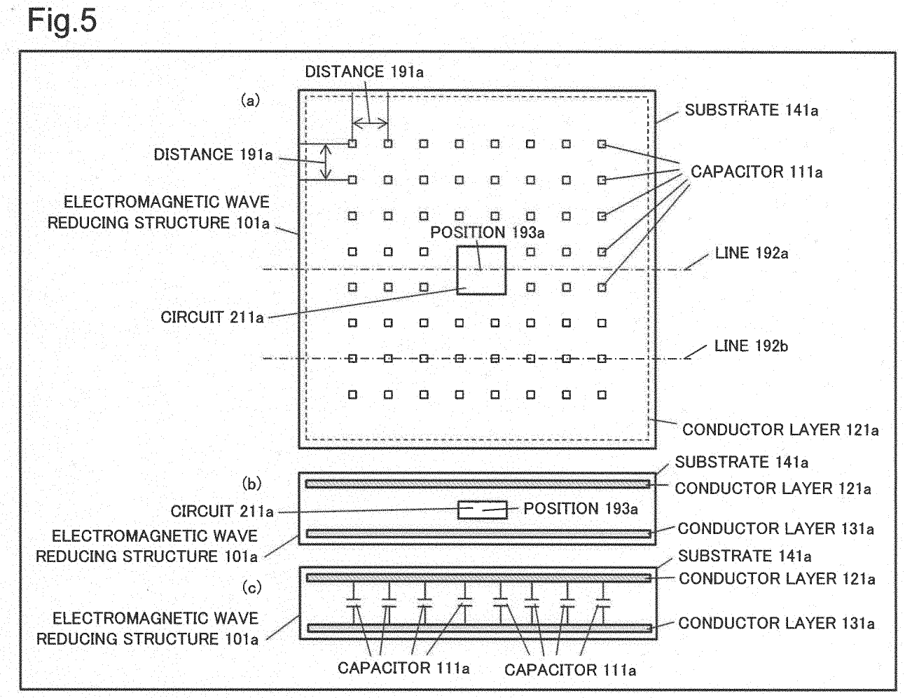

FIG. 5 is a concept diagram illustrating a state where a circuit 211a that is an example of the circuit is installed at the position 193a in the electromagnetic wave reducing structure 101a illustrated in FIG. 1.

For example, the circuit 211a is a circuit which is electrically connected to the conductor layer 121a as a power supply layer and to the conductor layer 131a as an installation layer, and receives voltage supplied from the conductor layer 121a. The circuit 211a is an integrated circuit, for example.

### [Simulation]

### <First Simulation>

Next, the description is made on the simulation result representing an electromagnetic wave reducing effect of the electromagnetic wave reducing structure 101a illustrated in FIG. 1 and FIG. 5.

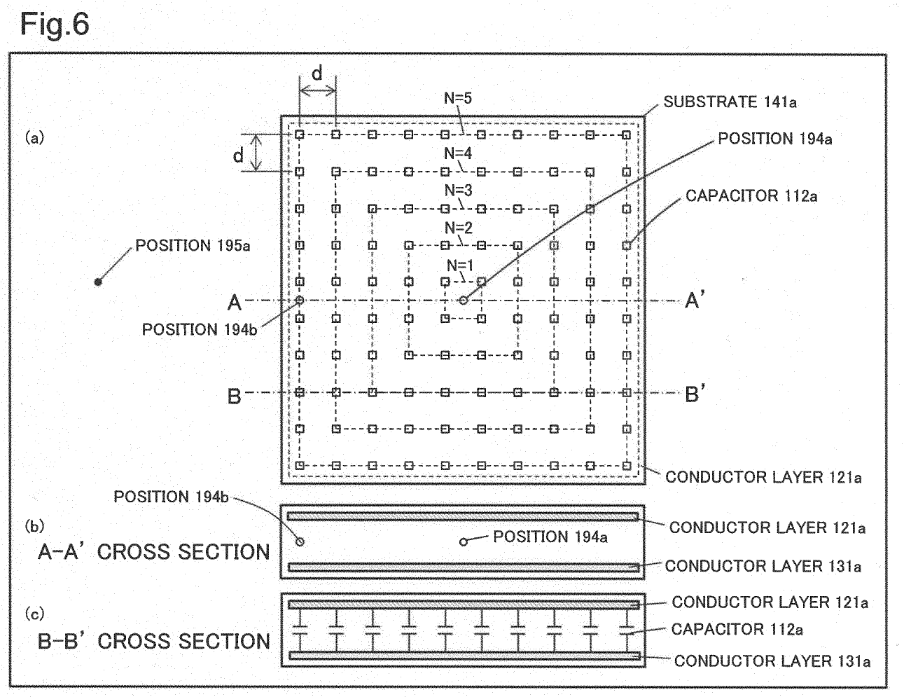

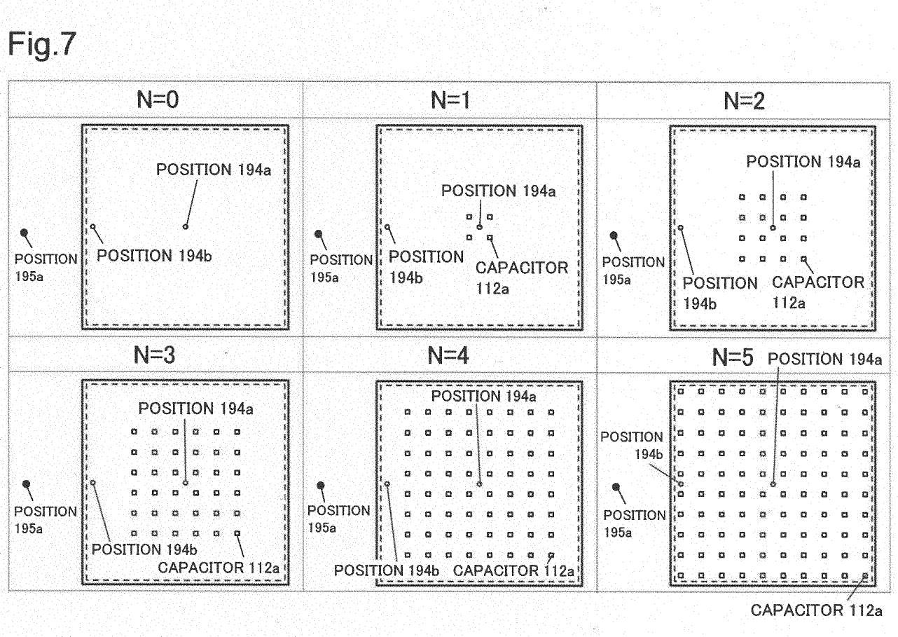

FIG. 6 and FIG. 7 are diagrams illustrating models of the electromagnetic wave reducing structure used in the simulation. FIG. 6(a) is a top view of the electromagnetic wave reducing structure. FIG. 6(b) is a cross-sectional view taken along a line A-A′ illustrated in FIG. 6(a). FIG. 6(c) is a cross-sectional view taken along a line B-B′ illustrated in FIG. 6(a).

All the smallest squares illustrated in FIG. 6(a) each represent a capacitor 112a. Further, all the capacitor symbols illustrated in FIG. 6(c) each represent the capacitor 112a.

Each of the capacitors 112a is formed between the conductor layer 121a and the conductor layer 131a. Every interval between one pair of the adjacent capacitors 112a is the same value of an interval d.

The simulation described below was performed for the respective cases (illustrated in FIG. 7) where the capacitors 112a are formed on respective squares of dotted lines respectively illustrated by N=1 to 5 in FIG. 6(a) and in the insides thereof. Note that N=0 corresponds to the case where none of the capacitors 112a are set.

It is assumed that a noise source that generates an electromagnetic wave noise is installed at a position 194a. The noise source corresponds to the circuit 211a illustrated in FIG. 5. It is assumed that an electromagnetic wave noise generated by the noise source is an electromagnetic wave noise having the same intensity in all the frequency regions.

Further, a position 194b is a position where an electromagnetic wave noise generated at the position 194a is assumed to be observed. Furthermore, a position 195a is a position where an electric field radiated from the position 194a is assumed to be observed.

The conditions used in the simulation are as follows. An interval d between a pair of the adjacent capacitors 112a is 7.5 mm. A relative dielectric constant of the substrate 141a is 4. An interval between a lower surface of the conductor layer 121a and an upper surface of the conductor layer 131a in FIG. 6(b) and FIG. 6(c) is 2 mm. An area of the conductor layer 121a in FIG. 6(a) is 5625 square millimeters (=75 mm×75 mm). It is assumed that the capacitor 112a is a series circuit of capacitance of 0.1 μF, an inductor of 0.35 nH, and a resistance of 19.4 mΩ.

These conditions were set on the assumption that an upper limit prevention frequency is 5 GHz. Here, the upper limit prevention frequency is an upper limit of a frequency of an electromagnetic wave noise that can be reduced by the electromagnetic wave reducing structure 101a.

Among the above-described assumptions, the interval between the lower surface of the conductor layer 121a and the upper surface of the conductor layer 131a, and the area of the conductor layer 121a were selected from values assumed on implementation when an integrated circuit is used as a circuit (refer to the circuit 211a in FIG. 5) that generates a noise.

Further, the assumption of the capacitance, the inductor and the resistance in the series circuit of the capacitor 112a is made based on the assumption that the upper limit prevention frequency is a resonance frequency of the series circuit. This assumption is understood to be appropriate from experience, and is understood to be appropriate also from the simulation result described below.

Further, the interval d is acquired by the assumption that approximately one fourth of a wavelength corresponding to the upper limit prevention frequency is the interval d. This assumption is understood to be appropriate from experience, and is understood to be appropriate also from the simulation result described below.

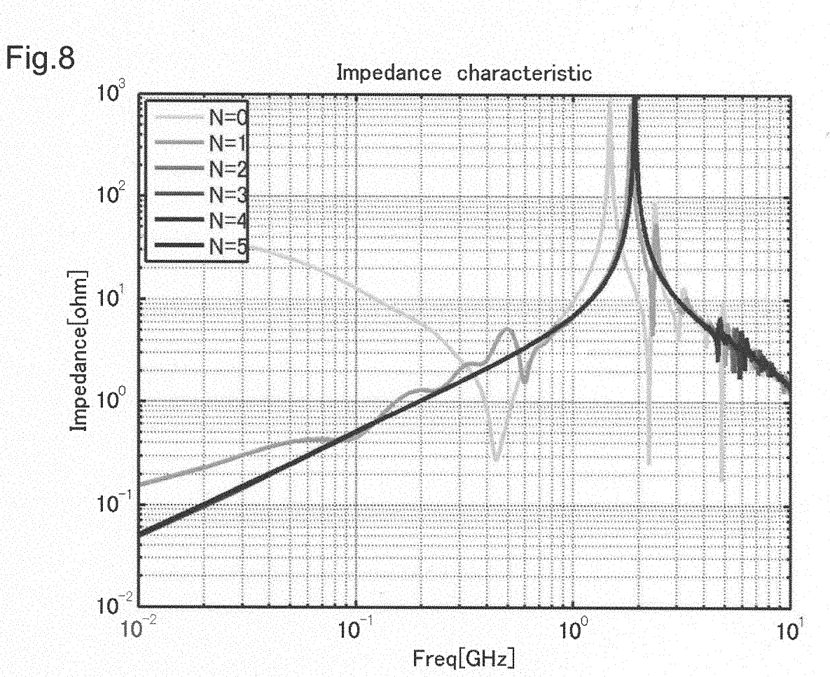

FIG. 8 illustrates a frequency characteristic of an impedance between the conductor layer 121a and the conductor layer 131a acquired by the simulation. The frequency characteristic of an impedance varies greatly between N=0 and N=1. This means that a decoupling effect appears by installing the capacitors 112a as in the case of N=1 in FIG. 7. Note that the decoupling effect is described in PTL 2, and thus, the description thereof is omitted here. Meanwhile, the frequency characteristic of an impedance does not greatly vary in N=1 to 5. This means that in N=1 to 5, even increasing the number of the capacitors 112a hardly influences the decoupling effect.

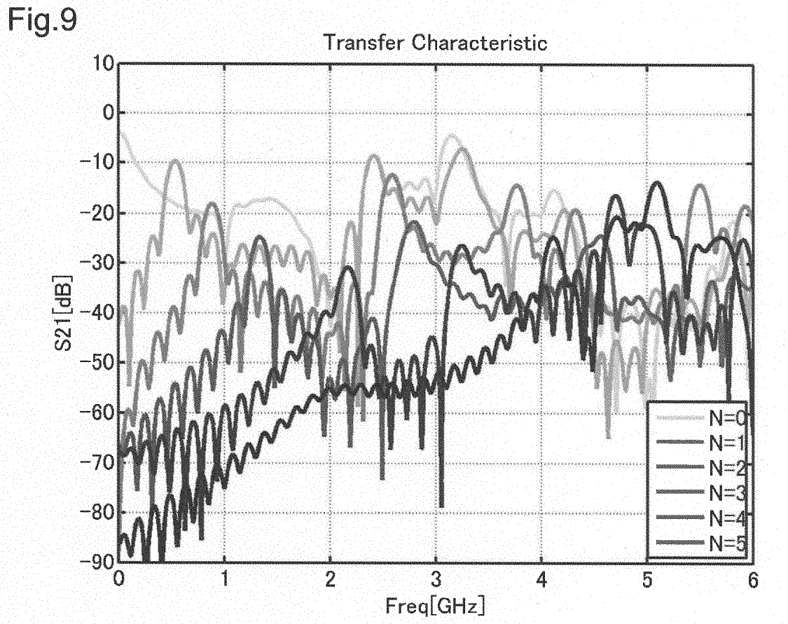

FIG. 9 is a diagram illustrating the simulation result of a noise propagation characteristic in the substrate 141a. FIG. 9 illustrates a frequency characteristic of S21 that is an amplitude value, observed at the position 194b, of an electromagnetic wave noise generated at the position 194a.

As compared with the case of N=0, in the case of N=1, no outstanding reduction in a value of S21 is observed. In contrast to this, as compared with the case of N=1, in the case of N=2, a value of S21 is outstandingly reduced particularly in a range equal to or lower than the vicinity of 5 GHz. When N is equal to or larger than 2, a value of S21 is more reduced as N becomes larger.

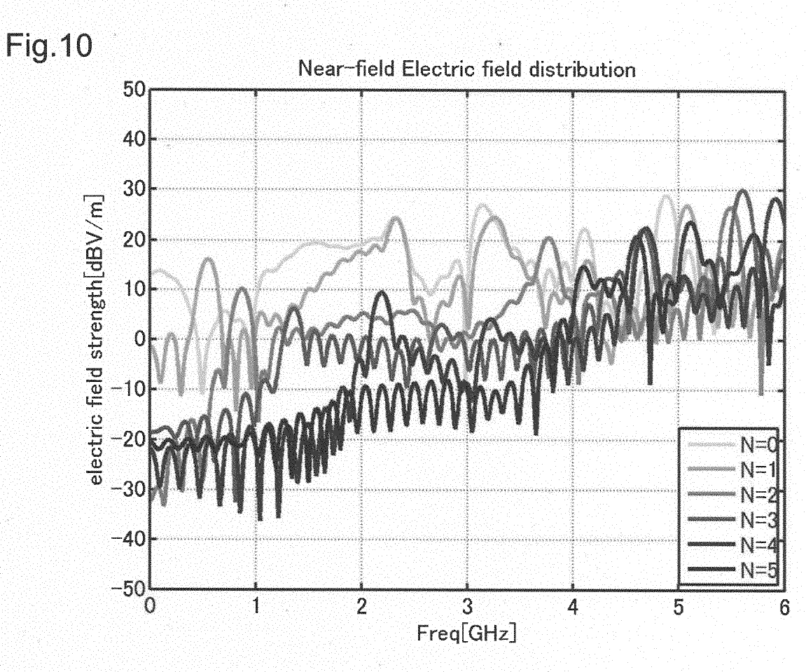

FIG. 10 is a diagram illustrating the simulation result of a characteristic of electric field radiation to an outside of the substrate 141a.

FIG. 10 illustrates a frequency characteristic of an electric field strength at the position 195a illustrated in FIG. 6.

As compared with the case of N=0, in the case of N=1, no outstanding reduction in an electric field strength is observed. In contrast to this, as compared with the case of N=1, in the case of N=2, an electric field strength is outstandingly reduced particularly in a range equal to or lower than 4.5 GHz. When N is equal to or larger than 2, an electric field strength is more reduced as N becomes larger.

As described above, when N is equal to or larger than 2, no further improvement in the decoupling effect is observed, but the simulation result that a noise propagation characteristic in the substrate 141a and a characteristic of electric field radiation to an outside of the substrate 141a are outstandingly improved was obtained.

According to the simulation result illustrated in FIG. 8 to FIG. 10, a noise propagation characteristic and a characteristic of electric field radiation to an outside of the substrate 141a are more improved as N becomes larger. However, larger N means that an area in the substrate 141a necessary for arranging the capacitors 112a becomes larger. For this reason, when N becomes larger, a mounting area in the substrate 141a for elements other than the capacitors 112a decreases. Further, because of necessity of arranging many capacitors 112a, the cost of manufacturing the electromagnetic wave prevention structure increases. Thus, it is considered that a more proper value of N is two or three.

### <Second Simulation>

Next, the description is made on a simulation result for an electromagnetic wave reducing structure in which the capacitors 112a are arranged in order from the vicinity of an outer periphery of a substrate.

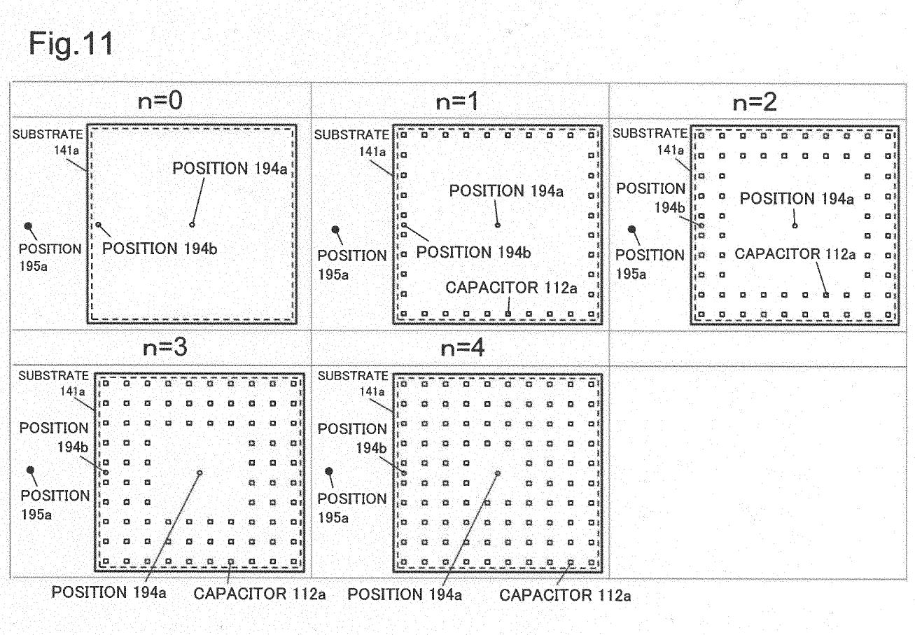

FIG. 11 is a diagram illustrating a model of an electromagnetic wave reducing structure used in the second simulation. FIG. 11 is a top view of the electromagnetic wave reducing structure. All the smallest squares illustrated in FIG. 11 each represent the capacitor 112a.

Although an illustration is omitted, conductor layers corresponding to the conductor layers 121a and 131a illustrated in FIG. 6 are formed on upper and lower sides inside the substrate 141a. The manner of forming the conductor layers is similar to that for the conductor layers 121a and 131a illustrated in FIG. 6. Hereinafter, these two conductor layers are referred to as conductor layers 121a and 131a.

Each of the capacitors 112a is formed between the conductor layer 121a and the conductor layer 131a. Every interval between one pair of the adjacent capacitors 112a is the same value of an interval d.

The second simulation described below was performed for the respective cases of n=0 to 4 illustrated in FIG. 11. In the case of n=0, none of the capacitors 112a are set. In the cases of n=1, 2, 3, and 4, the capacitors 112a are arranged in such a manner as to make 1, 2, 3, and 4 rounds respectively from an outer periphery of the substrate 141a.

It is assumed that a noise source that generates an electromagnetic wave noise is installed at the position 194a. It is assumed that an electromagnetic wave noise generated by the noise source is an electromagnetic wave noise having the same intensity in all the frequency regions.

Further, the position 194b is a position where an electromagnetic wave noise generated at the position 194a is assumed to be observed. Furthermore, the position 195a is a position where an electric field radiated from the position 194a is assumed to be observed.

The conditions used in the simulation are as follows. An interval d between a pair of the adjacent capacitors 112a is 7.5 mm. A relative dielectric constant of the substrate 141a is 4. An interval between a lower surface of the conductor layer 121a and an upper surface of the conductor layer 131a in FIG. 6(b) and FIG. 6(c) is 2 mm. An area of the conductor layer 121a in FIG. 6(a) is 5625 square millimeters (=75 mm×75 mm). It is assumed that the capacitor 112a is a series circuit of capacitance of 5.60×10⁻¹¹ F, an inductor of 4.50×10⁻¹⁰ H, and a resistance of 4.50×10⁻¹⁰Ω.

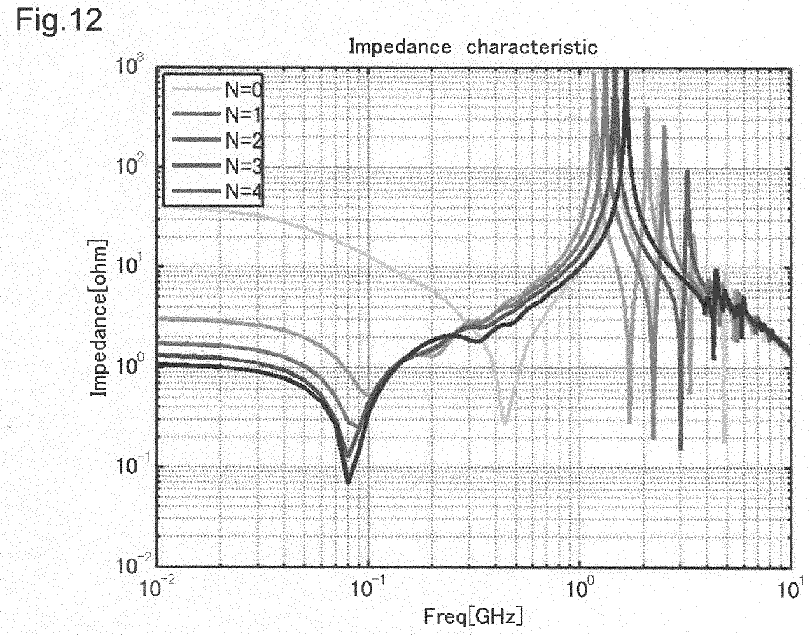

FIG. 12 illustrates a frequency characteristic of an impedance between the conductor layer 121a and the conductor layer 131a acquired by the second simulation. The frequency characteristic of an impedance varies greatly between n=0 and n=1. This means that a decoupling effect appears by installing the capacitors 112a as in the case of n=1 in FIG. 7. Note that the decoupling effect is described in PTL 2, and thus, the description thereof is omitted here. Meanwhile, the frequency characteristic of an impedance does not greatly vary in n=1 to 4. This means that in n=1 to 4, even increasing the number of the capacitors 112a does not greatly influence the decoupling effect.

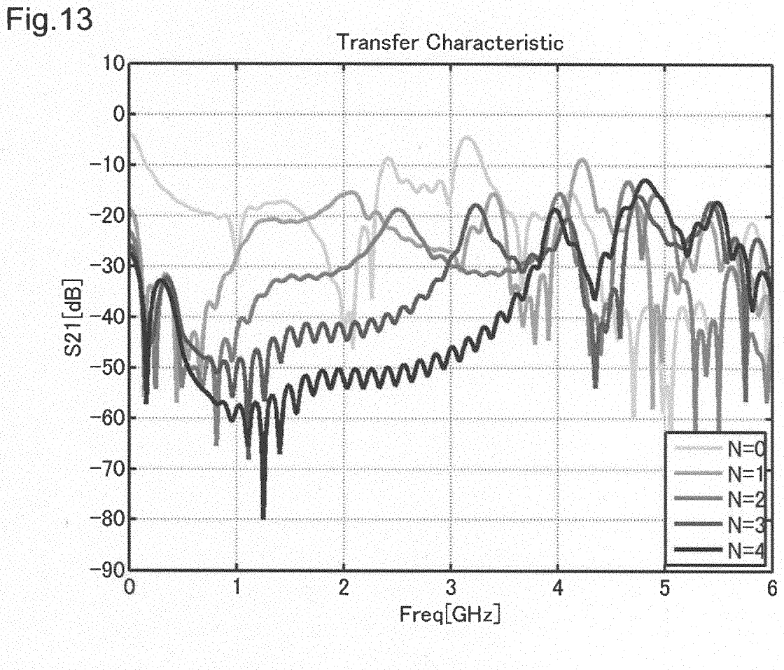

FIG. 13 is a diagram illustrating the result of the second simulation for a noise propagation characteristic in the substrate 141a. FIG. 13 illustrates a frequency characteristic of S21 that is an amplitude value, observed at the position 194b, of an electromagnetic wave noise generated at the position 194a illustrated in FIG. 11.

As compared with the case of n=0, in the case of n=1, no outstanding reduction in a value of S21 is observed. In contrast to this, as compared with the case of n=1, in the case of n=2, a value of S21 is reduced particularly in a range equal to or lower than the vicinity of 3 GHz. When n is equal to or larger than 2, a value of S21 is more reduced as n becomes larger.

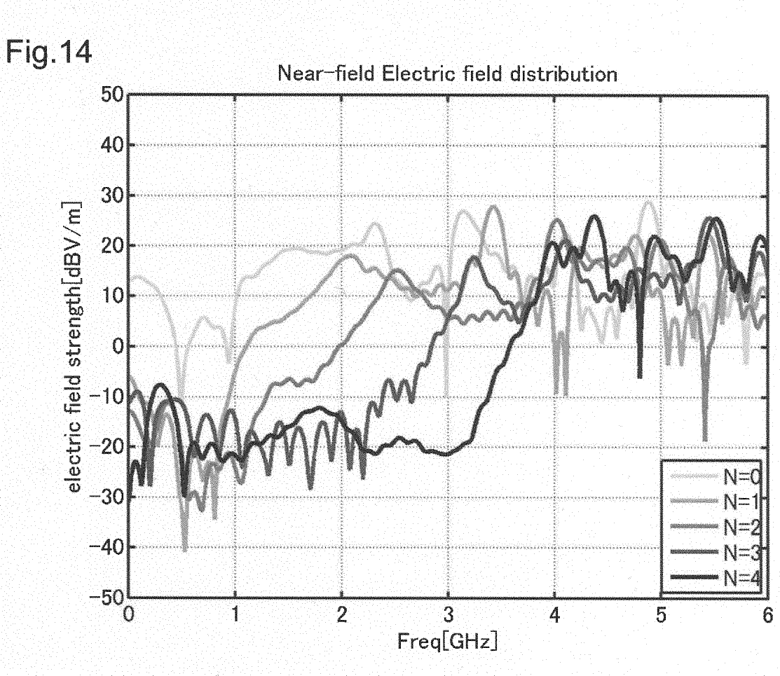

FIG. 14 is a diagram illustrating the result of the second simulation for a characteristic of electric field radiation to an outside of the substrate 141a. FIG. 14 illustrates a frequency characteristic of an electric field strength at the position 195a illustrated in FIG. 11.

As compared with the case of n=0, in the case of n=1, no outstanding reduction in an electric field intensity is observed. In contrast to this, as compared with the case of n=1, in the case of n=2, an electric field strength is outstandingly reduced particularly in a range equal to or lower than 4 GHz. When n is equal to or larger than 2, an electric field strength is more reduced as n becomes larger.

As described above, when n illustrated in FIG. 11 is equal to or larger than 2, no further improvement in the decoupling effect is observed, but the simulation result that a noise propagation characteristic in the substrate 141a and a characteristic of electric field radiation to an outside of the substrate 141a are outstandingly improved was obtained.

According to the simulation result illustrated in FIG. 12 to FIG. 14, a noise propagation characteristic and a characteristic of electric field radiation to an outside of the substrate 141a are more improved as n illustrated in FIG. 11 becomes larger. However, larger n means that an area in the substrate 141a necessary for arranging the capacitors 112a becomes larger. For this reason, when n becomes larger, a mounting area in the substrate 141a for elements other than the capacitors 112a decreases. Further, because of necessity of arranging many capacitors 112a, the cost of manufacturing the electromagnetic wave prevention structure increases. Thus, it is considered that a more proper value of n is two or three.

As described above, from the first and second simulations, it is understood that leakage, to an outside of the substrate, of an electromagnetic wave noise generated by the circuit can be prevented by arranging, around the circuit, a capacitor group constituted by the capacitors arranged at intervals equal to each other.

### [Variation of Capacitor Arrangement]

Next, the description is made on variations of arrangement of capacitors to a plurality of circuits that are formed in a substrate.

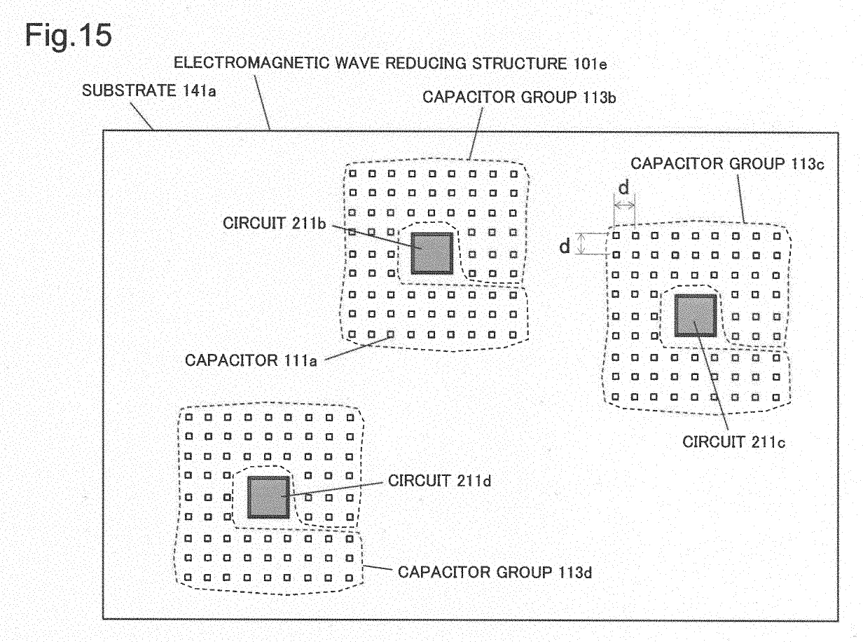

FIGS. 15 to 18 are concept diagrams illustrating examples of installation of the capacitors 111a in three circuits installed in a substrate.

FIG. 15 is a concept diagram illustrating an electromagnetic wave reducing structure 101e as a first example of an electromagnetic wave reducing structure in which the capacitors 111a are arranged to three circuits installed on a substrate. FIG. 15 illustrates, as the three circuits, circuits 211b, 211c, and 211d, as well.

In the electromagnetic wave reducing structure 101e, the circuits 211b, 211c, and 211d are respectively surrounded by capacitor groups 113b, 113c, and 113d constituted by the capacitors 111a. All the smallest squares illustrated in FIG. 15 each represent the capacitor 111a. In each of the capacitor groups 113b, 113c, and 113d, every interval between arbitrary one pair of the adjacent capacitors 111a is an interval d.

In the electromagnetic wave reducing structure 101e, by the above-described configuration, the respective capacitor groups 113b, 113c, and 113d prevent noises generated by the respective circuits 211b, 211c, and 211d, from being leaked to outsides of the respective capacitor groups 113b, 113c, and 113d. The electromagnetic wave reducing structure 101e prevents noises generated by the circuits 211b, 211c, and 211d, from influencing the others among the circuits 211b, 211c, and 211d.

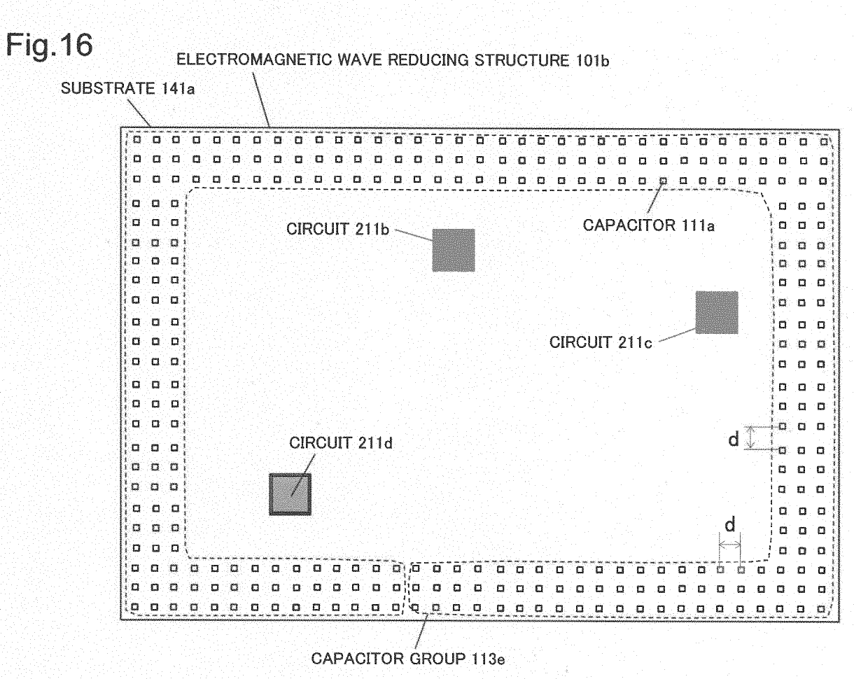

FIG. 16 is a concept diagram illustrating an electromagnetic wave reducing structure 101b as a second example of an electromagnetic wave reducing structure in which the capacitors 111a are arranged to three circuits installed on a substrate. FIG. 16 illustrates, as the three circuits, the three circuits 211b, 211c, and 211d, as well.

In the electromagnetic wave reducing structure 101b, a capacitor group 113e constituted by the capacitors 111a is provided along an outer periphery of the substrate 141a. The circuits 211b, 211c, and 211d are surrounded by the capacitor group 113e. All the smallest squares illustrated in FIG. 16 each represent the capacitor 111a. In the capacitor group 113e, every interval between arbitrary one pair of the adjacent capacitors 111a is an interval d.

The electromagnetic wave reducing structure 101b cannot prevent noises generated by the circuits 211b, 211c, and 211d, from reaching the others among the circuits 211b, 211c, and 211d. However, the electromagnetic wave reducing structure 101b can prevent noises generated by the circuits 211b, 211c, and 211d, from being released to an outside of the substrate 141a. The electromagnetic wave reducing structure 101b enables a relatively wide space for arranging the circuits 211b, 211c, and 211d to be secured on the inner side of the capacitor group 113e. Therefore, using the electromagnetic wave reducing structure 101b enables a freedom degree of arrangement of the circuits 211b, 211c, and 211d to be secured.

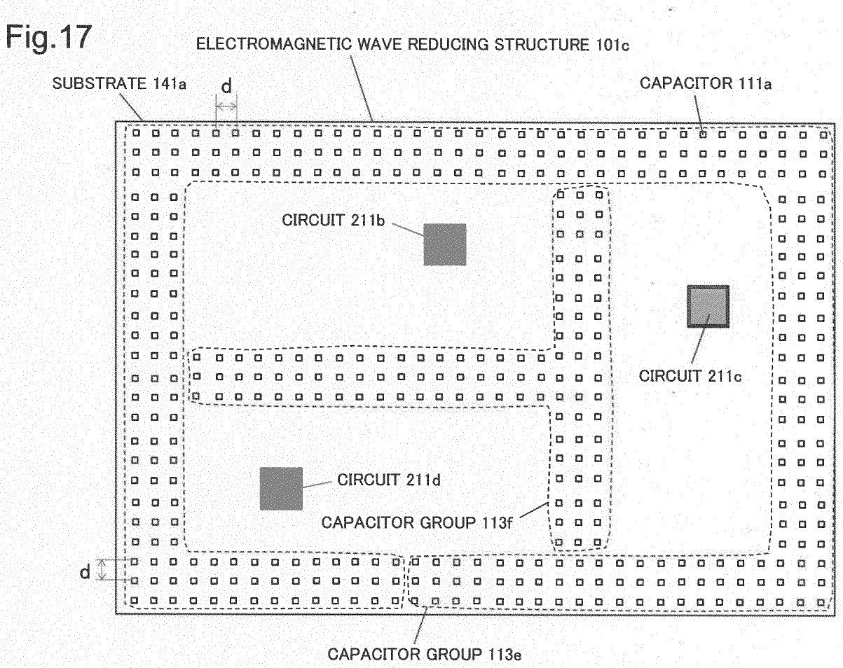

FIG. 17 is a concept diagram illustrating an electromagnetic wave reducing structure 101c as a third example of an electromagnetic wave reducing structure in which the capacitors 111a are arranged to three circuits installed on a substrate. FIG. 17 illustrates, as the three circuits, the three circuits 211b, 211c, and 211d, as well.

The electromagnetic wave reducing structure 101c includes a capacitor group 113f in addition to the configuration of the electromagnetic wave reducing structure 101b illustrated in FIG. 16. All the smallest squares illustrated in FIG. 17 each represent the capacitor 111a. In a capacitor group of a combination of the capacitor group 113e and the capacitor group 113f, every interval between arbitrary one pair of the adjacent capacitors 111a is an interval d.

Since the electromagnetic wave reducing structure 101c includes the capacitor group 113e, the electromagnetic wave reducing structure 101b can prevent noises generated by the circuits 211b, 211c, and 211d, from being released to an outside of the substrate 141a. In addition to this, in the electromagnetic wave reducing structure 101c, the capacitor group 113f exists between arbitrary two among the circuits 211b, 211c, and 211d. Therefore, the electromagnetic wave reducing structure 101c can prevent electromagnetic wave noises generated by the circuits 211b, 211c, and 211d, from reaching the others among the circuits 211b, 211c, and 211d.

The electromagnetic wave reducing structure 101c can further secure relatively large spaces in which the respective circuits 211b, 211c, and 211d can be arranged. Therefore, the electromagnetic wave reducing structure 101c enables a freedom degree of arrangement of the circuits 211b, 211c, and 211d to be secured to a certain degree.

However, in the electromagnetic wave reducing structure 101c, the number of capacitors 111a to be arranged is larger. As compared with the electromagnetic wave reducing structure 101c, the electromagnetic wave reducing structure 101e illustrated in FIG. 15 is advantageous in terms of the small number of the capacitors 111a to be arranged.

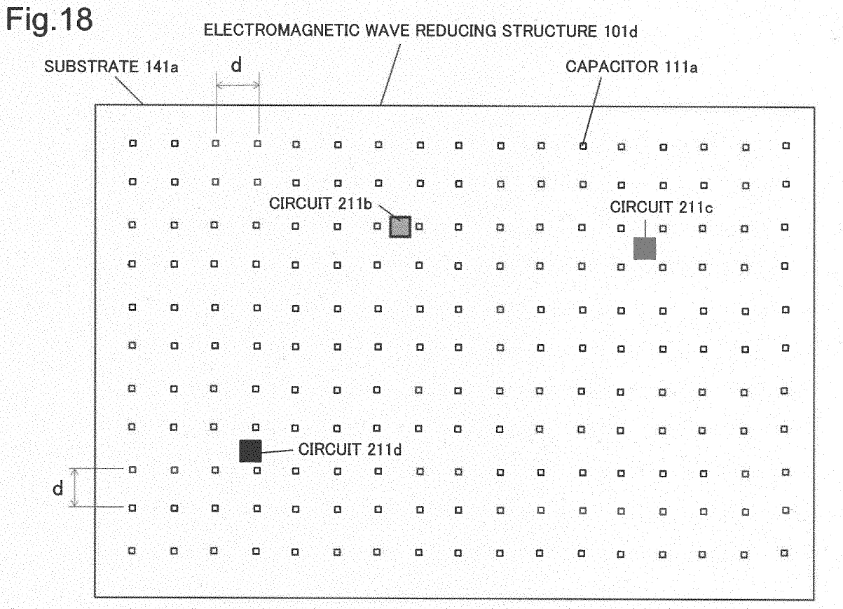

FIG. 18 is a concept diagram illustrating an electromagnetic wave reducing structure 101d as a fourth example of an electromagnetic wave reducing structure in which the capacitors 111a are arranged to three circuits installed on a substrate. FIG. 18 illustrates, as the three circuits, the three circuits 211b, 211c, and 211d, as well.

In the electromagnetic wave reducing structure 101d, the capacitors 111a are arranged on an entire surface of the substrate 141a. All the smallest squares illustrated in FIG. 18 each represent the capacitor 111a. Every interval between arbitrary one pair of the adjacent capacitors 111a is an interval d. The respective circuits 211b, 211c, and 211d are arranged among the capacitors 111a arranged on the entire surface of the substrate 141a.

The electromagnetic wave reducing structure 101d can prevent noises generated by the circuits 211b, 211c, and 211d, from being released to an outside of the substrate 141a. In the electromagnetic wave reducing structure 101c, the capacitors 111a exist between arbitrary two of the circuits 211b, 211c, and 211d. Therefore, the electromagnetic wave reducing structure 101d can prevent noises generated by the circuits 211b, 211c, and 211d, from reaching the others of the circuits 211b, 211c, and 211d. Further, when the electromagnetic wave reducing structure 101d is used, there is an advantage that a freedom degree of arrangement of the respective circuits 211b, 211c, and 211d are increased. However, the interval d needs to be large enough to arrange the circuits 211b, 211c, and 211d. For this reason, depending on sizes of the circuits 211b, 211c, 211d, the interval d is necessarily set to be large in some cases. From experience, it is understood that as the interval d is larger, an upper limit prevention frequency is lower. In order to make the upper limit prevention frequency higher, it is effective to decrease the interval d. In this respect, the electromagnetic wave reducing structures 101e, 101b, and 101c illustrated in FIG. 15 to FIG. 17 described above are superior to the electromagnetic wave reducing structure 101d illustrated in FIG. 18. This is because in the electromagnetic wave reducing structures 101e, 101b, and 101c, less restrictions due to sizes of the circuits 211b, 211c, and 211d exist concerning a decrease in the interval d.

### Advantageous Effects

As understood from the simulation result described above, the electromagnetic wave reducing structure according to the present example embodiment can reduce leakage, of an electromagnetic wave generated by the installed circuit, to an outside of the electromagnetic wave reducing structure according to the present example embodiment. The electromagnetic wave reducing structure according to the present example embodiment can make the above-described reduction in a range from a low-frequency region to a high-frequency region without using a special material difficult to acquire.

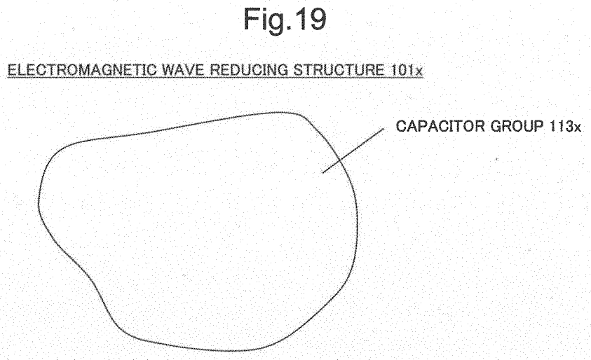

FIG. 19 is a concept diagram illustrating a configuration of an electromagnetic wave reducing structure 101x as the minimum configuration of an electromagnetic wave reducing structure according to the present invention.

The electromagnetic wave reducing structure 101x includes a first conductor layer and a second conductor layer that are not illustrated and face each other, and a capacitor group 113x constituted by a plurality of capacitors connected to the first conductor layer and the second conductor layer. A shape of the capacitor group 113x is not limited to the shape illustrated in the drawing, and is arbitrary.

All the intervals between the capacitors in a first direction and in a second direction are substantially equal to each other. Here, the first direction is an in-plane direction in a plane parallel to a surface that belongs to the first conductor layer and that faces the second conductor layer. The second direction is a direction in the plane and substantially perpendicular to the first direction.

The capacitor group 113x includes a plurality of rectangular arrays of capacitors in the plane, wherein the arrays surround an arrangement position of a circuit and do not overlap each other.

As understood from the simulation result described in the section of [Example Embodiment], the electromagnetic wave reducing structure 101x can reduce an amount of leakage, to an outside of the electromagnetic wave reducing structure 101x, of an electromagnetic wave noise generated by the circuit arranged at the arrangement position.

Therefore, by the above-described configuration, the electromagnetic wave reducing structure 101x achieves the advantageous effect described in the section of [Advantageous Effects of the Invention].

Although each of the example embodiments of the present invention is described above, the present invention is not limited to the above-described example embodiments, and further modifications, replacement, and adjustments may be made without departing from the basic technical idea of the present invention. For example, the configurations of the elements illustrated in the respective drawings are one example for facilitating understanding of the present invention, and are not limited to the configurations illustrated in these drawings.

The whole or part of the example embodiments disclosed above can be described as, but not limited to, the following supplementary notes.

### (Supplementary Note 1)

An electromagnetic wave reducing structure including:
a first conductor layer and a second conductor layer facing to each other; and a capacitor group constituted of a plurality of capacitors connected to the first conductor layer and the second conductor layer, wherein
every inter-capacitor interval between any one pair of the capacitors adjacent to each other in an in-plane first direction in a plane parallel to a surface that belongs to the first conductor layer and that faces the second conductor layer, and between any one pair of the capacitors adjacent to each other in a second direction that is a direction in the plane being substantially perpendicular to the first direction is substantially identical, and
the capacitor group includes a plurality of rectangular arrays of the capacitors in the plane, the arrays surrounding an arrangement position of a circuit and not overlapping each other.

### (Supplementary Note 2)

The electromagnetic wave reducing structure according to Supplementary note 1, wherein “the plurality of” means two or three.

### (Supplementary Note 3)

The electromagnetic wave reducing structure according to Supplementary note 1 or 2, wherein the first conductor layer is a layer for supplying voltage to the circuit.

### (Supplementary Note 4)

The electromagnetic wave reducing structure according to any one of Supplementary notes 1 to 3, wherein the second conductor layer is a layer for grounding the circuit.

### (Supplementary Note 5)

The electromagnetic wave reducing structure according to any one of Supplementary notes 1 to 4, wherein the first conductor layer and the second conductor layer are formed on a substrate.

### (Supplementary Note 6)

The electromagnetic wave reducing structure according to Supplementary note 5, wherein the first conductor layer and the second conductor layer are formed inside the substrate.

### (Supplementary Note 7)

The electromagnetic wave reducing structure according to Supplementary note 5 or 6, wherein the capacitor group is formed along an edge of the substrate.

### (Supplementary Note 8)

The electromagnetic wave reducing structure according to Supplementary note 7, wherein a plurality of the circuits are assumed to be installed, and the arrays are formed between respective assumed positions of the installation.

### (Supplementary Note 9)

The electromagnetic wave reducing structure according to Supplementary note 5 or 6, wherein the capacitor group is formed on an almost entire surface of the substrate.

### (Supplementary Note 10)

The electromagnetic wave reducing structure according to any one of Supplementary notes 1 to 9, wherein an area of the first conductor layer is in a vicinity of 5625 square millimeters.

### (Supplementary Note 11)

The electromagnetic wave reducing structure according to any one of Supplementary notes 1 to 10, wherein the first conductor layer is approximately a 75-millimeter square.

### (Supplementary Note 12)

The electromagnetic wave reducing structure according to any one of Supplementary notes 1 to 11, wherein the capacitor forms a series circuit of capacitance of approximately 0.1 μF, an inductor of approximately 0.35 nH, and a resistance of approximately 19.4 mΩ.

### (Supplementary Note 13)

The electromagnetic wave reducing structure according to any one of Supplementary notes 1 to 12, wherein an interval between the first conductor layer and the second conductor layer is approximately 2 mm.

### (Supplementary Note 14)

The electromagnetic wave reducing structure according to any one of Supplementary notes 1 to 13, further comprising the circuit.

While the invention has been particularly shown and described with reference to example embodiments thereof, the invention is not limited to these embodiments. It will be understood by those of ordinary skill in the art that various changes in form and details may be made therein without departing from the spirit and scope of the present invention as defined by the claims.

This application is based upon and claims the benefit of priority from Japanese patent application No. 2016-161324 filed on Aug. 19, 2016, the disclosure of which is incorporated herein in its entirety by reference.

### REFERENCE SIGNS LIST

101a, 101ab, 101ac, 101b, 101c, 101d, 101e, 101x Electromagnetic wave reducing structure
111a, 111aa, 111ab, 112a Capacitor
113b, 113c, 113d, 113e, 113f, 113x Capacitor group
121a, 121aa, 113a, 123a, 131a Conductor layer
122a Conductor
114a, 124a Terminal
141a, 141aa, 141ab, 141ac, 141ad Substrate
142aa, 142ab, 142b, 143a Insulator
191a Distance
192a, 192b Line
193a, 194a, 194b, 195a Position
196a, 197a, 197b Hole
211a, 211b, 211c, 211d Circuit

What is claimed is:

1. An electromagnetic wave reducing structure including:
a first conductor layer and a second conductor layer facing to each other; and a capacitor group constituted of a plurality of capacitors connected to the first conductor layer and the second conductor layer, wherein
every inter-capacitor interval between any one pair of the capacitors adjacent to each other in an in-plane first direction in a plane parallel to a surface that belongs to the first conductor layer and that faces the second conductor layer, and between any one pair of the capacitors adjacent to each other in a second direction that is a direction in the plane being substantially perpendicular to the first direction is substantially identical, and
the capacitor group includes a plurality of rectangular arrays of the capacitors in the plane, the arrays surrounding an arrangement position of a circuit and not overlapping each other.

2. The electromagnetic wave reducing structure according to claim 1, wherein “the plurality of” means two or three.

3. The electromagnetic wave reducing structure according to claim 1, wherein the first conductor layer is a layer for supplying voltage to the circuit.

4. The electromagnetic wave reducing structure according to claim 1, wherein the second conductor layer is a layer for grounding the circuit.

5. The electromagnetic wave reducing structure according to claim 1, wherein the first conductor layer and the second conductor layer are formed on a substrate.

6. The electromagnetic wave reducing structure according to claim 5, wherein the first conductor layer and the second conductor layer are formed inside the substrate.

7. The electromagnetic wave reducing structure according to claim 5, wherein the capacitor group is formed along an edge of the substrate.

8. The electromagnetic wave reducing structure according to claim 7, wherein a plurality of the circuits are assumed to be installed, and the arrays are formed between respective assumed positions of the installation.

9. The electromagnetic wave reducing structure according to claim 5, wherein the capacitor group is formed on an almost entire surface of the substrate.

10. The electromagnetic wave reducing structure according to claim 1, wherein an area of the first conductor layer is in a vicinity of 5625 square millimeters.

11. The electromagnetic wave reducing structure according to claim 1, wherein the first conductor layer is approximately a 75-millimeter square.

12. The electromagnetic wave reducing structure according to claim 1, wherein the capacitor forms a series circuit of capacitance of approximately 0.1 pF, an inductor of approximately 0.35 nH, and a resistance of approximately 19.4 mΩ.

13. The electromagnetic wave reducing structure according to claim 1, wherein an interval between the first conductor layer and the second conductor layer is approximately 2 mm.

14. The electromagnetic wave reducing structure according to claim 1, further comprising the circuit.
